(19) United States
(12) Patent Application Publication
(10) Pub. No.: US 2020/0118906 A1
(43) Pub. Date: Apr. 16, 2020

(54) GAP FILLERS WITH INDEPENDENTLY TUNABLE MECHANICAL AND THERMAL PROPERTIES

(71) Applicant: Carbice Corporation, Atlanta, GA (US)

(72) Inventors: Baratunde Cola, Atlanta, GA (US); Craig Green, Atlanta, GA (US)

(21) Appl. No.: 16/654,974

(22) Filed: Oct. 16, 2019

Related U.S. Application Data
(60) Provisional application No. 62/746,378, filed on Oct. 16, 2018.

(51) Int. Cl. H01L 23/42; H01L 23/373

(52) U.S. Cl. CPC H01L 23/42; H01L 23/3735; H01L 23/3737; H01L 51/0048; H01L 2924/0002; H01L 23/3738; H01L 23/3736

(57) ABSTRACT

Gap pads or gap fillers having independently tunable mechanical and thermal properties and methods of making and using thereof are described herein. The gap pads or gap fillers described can be used, for example, to interface a heat generating source and a heat sink.

### CROSS-REFERENCE TO RELATED APPLICATIONS

This application claims benefit of and priority to U.S. Provisional Application No. 62/746,378, filed on Oct. 16, 2018, which is hereby incorporated herein by reference in its entirety.

### FIELD OF THE INVENTION

This invention is in the field of gap pads or gap fillers with tunable properties which interface, for example, energy sources and heat sinks, as well as methods of making and using thereof.

### BACKGROUND OF THE INVENTION

Compressible compliant energy conducting materials typically consist of composites or mixtures which may be formable or formed from compressible materials (e.g. greases, gels, elastomers) and can further contain energy conducting fillers (e.g. metal, semiconductors, ceramics, carbon, etc.) Energy conducting materials, such as fillers, are typically solids. Such fillers, however, change the mechanical properties of the compressible matrix so that the energy conducting properties and mechanical properties cannot be tuned independently. Further, interfaces present between filler materials limit the achievable effective energy conductivity through such materials.

For example, silicone rubber may be made thermally or electrically conductive through the incorporation of fillers. However, as filler loading increases the compression set of the rubber material increases in kind. Existing compressible or formable thermally conductive materials typically have a high compression set whereas low compression set is important for dynamic applications, such as chip testing, where the thermal interface must engage with possibly thousands or more unique components. Such interfaces undergo thermal expansion during operation.

For at least the foregoing reasons, there is a demand for energy conducting materials which are compliant gap fillers or pads for interfacing with energy sources and sinks.

Therefore, it is an object of the present invention to provide such gap pads or gap fillers which are compliant and have independently tunable properties.

It is a further object of the present invention to describe methods of manufacturing such gap fillers or pads having tunable properties.

It is yet another object of the present invention to provide uses for such gap fillers or pads which can, for example, be placed between a heat-generating source and a sink.

### SUMMARY OF THE INVENTION

Gap pads and gap fillers having independently tunable mechanical and thermal and/or electrical properties and methods of making and using the same are described herein.

The gap pads and gap fillers having independently tunable mechanical and thermal and/or electrical properties described include at least one compressible and/or compliant core component and at least one layer of a heat transporting and/or electrically conducting material wrapping the at least one compressible and/or compliant core component.

The compressible and/or compliant core component(s) may be formed or obtained to have any dimension needed. Methods of preparing and forming compressible and/or compliant core components from such materials as described above and having requisite dimensions needed for forming a core component for a gap pad or filler described herein are known.

The heat transporting and/or electrically conducting material which wrap around the core component can be a flexible foil or sheet or a flexible laminate material. The heat transporting and/or electrically conducting material layer can be a flexible foil or sheet of a metal or a metal alloy; or a flexible graphite or synthetic graphite sheet; or a flexible laminate material which is formed of a carbon-based material which optionally further includes a foil or a foil comprising an array of carbon nanotubes.

For the gap fillers or gap pads the heat transporting and/or electrically conducting material typically has a thermal conductivity in the range of between about 1-2500 W/m·K, 1-2000 W/m·K, 1-1500 W/m·K, 1-1000 W/m·K, 1-500 W/m·K, 5-500 W/m·K, 5-400 W/m·K, 5-300 W/m·K, 5-200 W/m·K, 5-150 W/m·K, or 5-100 W/m·K. In some instances, a thermal conductivity of 100-1900 W/m·K is preferred. The presence of the heat transporting and/or electrically conducting material provides increased thermal conductivity of at least about 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, 20 times, 21 times, 22 times, 23 times, 24 times, 25 times, 50 times, 100 times, or greater, as compared to the thermal conductivity of a gap filler or gap pad excluding a heat transporting and/or electrically conducting material present thereon.

The thermal contact resistance of the gap pads or gap fillers is typically reduced by at least about 25%, 30%, 35%, 40%, 45%, 50%, 55%, 60%, 65%, 70% or greater when the gap pads or gap fillers include a heat transporting and/or electrically conducting material, when measured, for example, using transient structure function analysis. In certain embodiments, the gap pads or gap fillers exhibit thermal resistances of less than about 2.0, 1.5, 1.0, 0.9, 0.8, 0.7, 0.6, 0.5, 0.4, 0.3, 0.2, or 0.1 cm² K/W, as compared to gap pads or gap fillers without the inclusion of a heat transporting and/or electrically conducting material wrapped around the core component(s).

The primary direction of heat flow, when the gap pads or fillers are placed between a heat source and a sink, is associated with the heat transporting and/or electrically conducting material which is wrapped around the core component.

In some instances, the heat transporting and/or electrically conducting material has an electrical resistance of less than about 1000, 900, 800, 700, 600, 500, 400, 300, 200, 100, 75, 50, 25, 20, 15, 10, 9, 8, 7, 6, 5, 4, 3, 2, 1, 0.9, 0.8, 0.7, 0.6, 0.5, 0.4, 0.3, 0.2, or 0.1 milliohms. The inclusion of the heat transporting and/or electrically conducting material provides increased electrical conductivity of at least about 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, 20 times, 21 times, 22 times, 23 times, 24 times, 25 times, 50 times, 100 times, 1000 times, or greater, as compared to the electrical conductivity of a gap filler or gap pad excluding a heat transporting and/or electrically conducting material present thereon.

The primary direction of electrical energy flow, when the gap pads or fillers are placed between electrical components, is associated with the heat transporting and/or electrically conducting material which is wrapped around the core component. In some instances, the primary direction of electrical flow direction is associated and/or controlled by the heat transporting and/or electrically conducting material which is wrapped around the core component.

In some instances there is only one layer of heat transporting and/or electrically conducting material wrapped around one or more core component(s). In some other cases there may be multiple layers wrapped around the core component(s), such as two, three, four, five, six, seven, eight, nine, or more layers of the at least one layer of a heat transporting and/or electrically conducting material.

Multiple layers of the heat transporting and/or electrically conducting material may be concentrically wrapped around the at least one compressible and/or compliant core component. In other instances, the heat transporting and/or electrically conducting material may be wrapped in a serpentine manner. In certain cases, where there are multiple compressible and/or compliant core components each component can be independently wrapped by the heat transporting and/or electrically conducting material or they may all together be wrapped by one or more layers of the heat transporting and/or electrically conducting material.

The heat transporting and/or electrically conducting material, which may be a foil, sheet, or laminate, typically has a thickness in a range of between about 0 μm to 250 μm, preferably between 17 μm to 100 μm. The size of the heat transporting and/or electrically conducting material needed to wrap one or more core components can be determined as needed. For example, a sufficient size of a foil, sheet, or laminate of heat transporting and/or electrically conducting material can be formed or obtained needed to wrap the compressible/compliant core components, as needed.

The gap filler or gap pads described above may further include: an interfacing material present on at least one surface of the heat transporting and/or electrically conducting material surrounding the at least one compressible and/or compliant core component. The interfacing material may be present on specific surfaces of the gap filler or pad. For example, when the gap filler or pad is placed between a heat source and a sink the interfacing material may be present only on the surfaces of the gap pad or filler that are in direct contact with the surface(s) of the heat source and the sink.

In some instances, the electrical conductivity of the heat transporting and/or electrically conducting material, which is wrapped around the core component(s), can serve as an electrical shield. In these instances, the heat transporting and/or electrically conducting material can prevent and/or block all or substantially all of the transmission of electromagnetic waves through or normal to the surface of the heat transporting and/or electrically conducting material (“substantially all” refers to preventing/blocking at least about 95%, 97%, 98%, 99%, 99.9%, or greater of the transmission of electromagnetic waves, as compared to in the absence of the transporting and/or electrically conducting material). The heat transporting and/or electrically conducting materials and interfacing materials wrapped around the core component(s) may be placed such that there are no seams or minimal number of seams or material transitions in the path of a transmitted electromagnetic wave. Minimizing the presence of seams or material transitions in the signal path will reduce the potential for passive intermodulation inside of a waveguide.

In some instances, two, three, four, five, six, seven, eight, nine, ten, or more of the compressible and/or compliant core components are each wrapped by the heat transporting and/or electrically conducting material and the interfacing material acts as a heat spreader or coupler between the wrapped compressible and/or compliant core components.

The gap pads or gap fillers described herein can be conformable and flexible. The gap pads or gap fillers can conform to a device's dimensions, and elastically deform or deflect under installation force. The gap pads or gap fillers can conform to flat, non-flat, undulating, or other uniform or non-uniform surface shapes and provide a good thermal interface independent of a heat-generating device's surface flatness. In most instances, the gap pads or gap fillers conform to contact all of the desired surface, such as of a heat sink or a heat generating source/device, which is to be contacted with the gap pads or gap fillers or substantially all of the surface (i.e., “substantially all,” refers to at least about 90%, 91%, 92%, 93%, 94%, 95%, 96%, 97%, 98%, or 99%, or higher). In some instances, the gap pads or gap fillers can conform to contact multiple devices or components thereof within the same substrate or system.

The gap pads or gap fillers preferably conform to contact all of the desired surface of a heat generating source, such as a device, which is to be contacted with the gap pads or gap fillers or substantially all of the surface desired and traps no or a minimum amount of air or voids and provides intimate contact between the surface interfaces contacted by the gap pads or gap fillers. The flexible and conformable gap pads or gap fillers conform to heat-generating surfaces and minimize gaps. Flexibility and conformability allow for the gap pads or gap fillers to be flattened or smoothed, as needed, to mate well or completely to the surface(s) of a heat-generating source or heat sink, or the like.

The flexibility and compressibility of the core component of the flexible and conformable gap pads or gap fillers allow bending or flexing, deflecting, and/or absorbing forces (e.g., impact force, shock force, vibration force with variable energy and duration). In some instances, the gap pads or gap fillers can act as a vibration damper or shock isolator to the heat generating source and/or heat sink to which it forms an interface between.

The gap fillers or gap pads described herein may be formed according to a method as follows.

A non-limiting exemplary method of forming a gap pad or gap filler includes the steps of:

(a) providing at least one compressible and/or compliant core component; and at least one heat transporting and/or electrically conducting material; and

(b) wrapping the at least one heat transporting and/or electrically conducting material around the at least one compressible and/or compliant core component; and

wherein step (b) optionally includes applying an adhesive to the at least one heat transporting and/or electrically conducting material to maintain the position of the wrapped at least one heat transporting and/or electrically conducting material on the compressible core.

The methods described can include further steps of:

(c) providing an interfacing material; and

(d) contacting the interfacing material to at least one surface of the heat transporting and/or electrically conducting material wrapped around the at least one compressible and/or compliant core component.

The gap filler or pads formed according to the methods noted herein can have any suitable dimensions needed to cover and/or contact one or more surfaces of a heat-generating device (such as a computer chip or component) or to cover and/or contact one or more surfaces of a heat sink.

The gap fillers or gap pads described herein are well suited for applications where they are interfacing a heat sink and heat generating source and can conform to sources of such heat sinks or heat generating devices, such as computer chips, computer modules, multi-component system, electronic devices (i.e., displays), etc. Such heat generating sources typically demonstrate non-planarity where such non-planarity may be a result of warpage or curvature due to manufacture or manufacturing tolerances, thermal expansion during use, or mechanical stress/strain during assembly or use.

The gap pad or gap filler can be used to accommodate differences in height between multiple components which are located on a same substrate. The gap pad or gap filler can also be used to accommodate differences in height between multiple components of different heights interfacing with a single planar secondary surface, such as a heat sink. The gap pad or gap filler can also be used to accommodate or fill a curvature of a first surface to improve contact with a second surface with a different curvature. In yet another example, the gap pad or gap filler can be used to accommodate manufacturing tolerances of a part that is otherwise not made to precise or tightly controlled flatness.

### BRIEF DESCRIPTION OF THE DRAWINGS

FIG. 1A shows a non-limiting illustration of a short-length gap filler or gap pad 100 having a compressible and/or compliant core component 110 formed of an elastomer and three layers of a heat transporting and/or electrically conducting material 120 wrapped around component 110.

FIG. 1B shows a non-limiting illustration of a long-length gap filler or gap pad 100 having a compressible and/or compliant core component 110 formed of an elastomer and three layers of a heat transporting and/or electrically conducting material 120 wrapped around component 110.

FIG. 1C shows a non-limiting illustration of a multi-component gap filler or gap pad 100 having three compressible and/or compliant core components 110 formed of an elastomer, which are aligned in a linear array, and three layers of a heat transporting and/or electrically conducting material 120 wrapped around each of the three 110 components.

FIG. 2A shows a non-limiting illustration of a gap filler or gap pad 200 having a compressible and/or compliant core component 210 formed of an elastomer and a layer of a heat transporting and/or electrically conducting material 220 wrapped around component 210. Gap filler or gap pad 200 is at least in partial contact (i.e., wrapped) with an interfacing material 230.

FIG. 2B shows a non-limiting illustration of a multi-component gap filler or gap pad 300 having three compressible and/or compliant core components 310 formed of an elastomer, which are aligned in a linear array, and a layer of a heat transporting and/or electrically conducting material 320 wrapped around each of the three 310 components. Gap filler or gap pad 300 is at least in partial contact (i.e., wrapped) with an interfacing material 330.

FIG. 3A shows a non-limiting illustration of a gap filler or gap pad 100 having a compressible and/or compliant core component 110 formed of an elastomer and a layer of a heat transporting and/or electrically conducting material 120 wrapped around component 110. Gap filler or gap pad 100 is shown between a heat source and a heat sink and the arrows depict the direction of heat flow from the heat source to the heat sink via gap filler or gap pad 100. Spaces shown in the illustration between the gap filler or gap pad and the heat source and heat sink are not representative and are included to allow heat flow to be depicted, as the gap filler or gap pad is in contact with the heat source and heat sink.

FIG. 3B shows a non-limiting illustration of a gap filler or gap pad 200 having a compressible and/or compliant core component 210 formed of an elastomer and a layer of a heat transporting and/or electrically conducting material 220 wrapped around component 210. Gap filler or gap pad 200 is at least in partial contact (i.e., wrapped) with an interfacing material 230. Gap filler or gap pad 200 is shown between a heat source and a heat sink and the arrows depict the direction of heat flow from the heat source to the heat sink via gap filler or gap pad 200. Spaces shown in the illustration between the gap filler or gap pad and the heat source and heat sink are not representative and are included to allow heat flow to be depicted, as the gap filler or gap pad is in contact with the heat source and heat sink.

FIG. 3C shows a non-limiting illustration of a multi-component gap filler or gap pad 300 having three compressible and/or compliant core components 310 formed of an elastomer, which are aligned in a linear array, and a layer of a heat transporting and/or electrically conducting material 320 wrapped around each of the three 310 components. Gap filler or gap pad 300 is at least in partial contact (i.e., wrapped) with an interfacing material 330. Gap filler or gap pad 300 is shown between a heat source and a heat sink and the arrows depict the direction of heat flow from the heat source to the heat sink via gap filler or gap pad 300. Spaces shown in the illustration between the gap tiller or gap pad and the heat source and heat sink are not representative and are included to allow heat flow to be depicted, as the gap filler or gap pad is in contact with the heat source and heat sink.

FIG. 4 shows a non-limiting illustration of a method of wrapping a compressible and/or compliant core component 110 formed of an elastomer with a heat transporting and/or electrically conducting material 120. The arrows shown in the figure are illustrative of the wrapping of component 110 with material 120.

FIG. 5 shows a non-limiting illustration of a method of wrapping four gap pads or fillers 100 (each formed of an elastomer wrapped with a heat transporting and/or electrically conducting material) and wrapped with interfacing material 330. The arrows shown in the figure are illustrative of the wrapping of the four gap fillers or pads, 110, with material 330.

FIG. 6 shows a non-limiting illustration of two gap filler or gap pads, each having a compressible and/or compliant core components 410 formed of an elastomer and each having a layer of a heat transporting and/or electrically conducting material 420 wrapped around each of components 410. The two gap filler or gap pads are each shown at least in partial contact (i.e., wrapped) with an interfacing material 430. The two gap filler or gap pads are each in between waveguide flanges 440. Spaces shown in the illustration between the gap filler or gap pads and the waveguide flanges are included for ease of depicting the arrangement are not representative, as the gap filler or gap pads are sandwiched and in contact with the waveguide flanges 440. As shown, transmission of electromagnetic waves (i.e., radiofrequency (RF) signal(s)) 450 can prevented or blocked by the presence of the gap filler or gap pads placed between the waveguide flanges.

### DETAILED DESCRIPTION OF THE INVENTION

Gap pads and gap fillers having independently tunable mechanical and thermal and/or electrical properties and methods of making and using the same are described below.

### I. Definitions

“Compressible,” as used herein refers to a material that reduces in size when subjected to inward (compressive) pressure, force, or load. A material is considered compressible when it exhibits a significant (>5%) change in nominal dimension when subjected to compressive force.

“Compliant,” as used herein refers to a material that easily deforms when subjected to a load to fill the contours of the surface or material that it is in contact with. To be considered compliant, a material should be deformable to fill the contours of the mating surface at a pressure or load lower than that seen in typical use cases or assembly processes. In some applications a compliant material may need to deform to fill the contours of the mating surface at a load of less than 100 psi. In many applications, a compliant material may need to deform to fill the contours of the mating surface at a load of less than 50 psi. In applications will fragile components such are unlidded silicon, a compliant material may need to deform to fill the contours of the mating surface at a load of less than 15 psi.

“Elastomer,” as used herein refers to a polymer that deforms elastically under relevant loads. In other words, an elastomer is a polymer that when subjected to compressive loading below the material's plastic deformation limit, the material recovers all or most of its original shape and volume after removal of the load.

“Spring,” as used herein refers to a mechanical device that stores compressive force as potential energy when subjected to load. When subjected to compressive load, the spring undergoes a change in characteristic length scale (e.g. coil length in coil springs, chord length or radius in leaf springs, etc.). The spring releases the stored energy when the compressive load is removed, relaxing to its uncompressed length.

“Sponge,” as used herein refers to a bulk material with a repeating substructure of void spaces within the bulk. The void spaces may be open or closed cells, or a structured lattice network. For closed cell sponges the void may be filled with gases. The cells, and the voids within the cells impart softness and compressibility to the bulk material.

“Foam,” as used herein refers to a type of sponge created using blowing agents during manufacture to create the cellular structure.

“Hardness,” as used herein refers to the resistance of a material deformation due to a constant compression load.

“Elastic modulus,” as used herein refers to the measure of a material's resistance to being deformed elastically (i.e., non-permanently) when subjected to stress. The elastic modulus of an object is defined as the slope of its stress-strain curve in the elastic deformation region.

“Outgassing,” as used herein refers to the tendency of a material to release gas that was trapped, adsorbed, absorbed, mixed, frozen, dissolved, or otherwise incorporated into the base material. Outgassing often occurs due to due to exposure to low pressure (vacuum), high temperature, or concentration gradient. ASTM E595 is a common method for quantifying “low” outgassing. It is a standard that looks at total mass loss (TML<1% initial mass) as well as percent of material that recondensed (collected volatile condensable materials CVCM<0.1% initial mass) under test conditions (125° C. at less than 5×10⁻⁵ torr)

“Compression set,” as used herein refers to the permanent (non-recoverable, inelastic) compression of a material observed after being subjected to compressive load. Compression set as a percentage of the original thickness is computed as follows:

C=tₒ−t_{f}/tₒ×100%

where:
C=Compression set as a percentage of the original thickness,
to=original thickness, and
t_{f}=final thickness

“Conformable,” “Compliant,” or “Compliance,” are used interchangeably herein, and refer to the ability of a material to conform or deform when the material is contacted, typically under an applied pressure (i.e., compression force), to one or more surfaces such that efficient conformance to the asperities, curvature, and/or nonplanarity of the adjoining surface results in sufficient or high contact areas at the interfaces between the one or more surfaces and the material.

“Carbon Nanotube Array” or “CNT array”, as used herein, refers to a plurality of carbon nanotubes which are vertically aligned on a surface of a substrate material. Carbon nanotubes are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

“Carbon Nanotube Sheet” or “CNT sheet”, as used herein, refers to a plurality of carbon nanotubes which are aligned in plane to create a free-standing sheet. Carbon nanotubes are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

“Heat transporting,” as used herein refers to a material capable of transferring/conducting thermal energy. Such materials may include metals or alloys or carbon-based materials which have high thermal conductivities, such as copper, aluminum, graphite, and arrays of carbon nanotubes, etc.

“Electrically conducting,” as used herein refers to a material that allows for the flow of electrical current and has a sufficiently low electrical resistance. Such materials may include metals or alloys or carbon-based materials which have high electrical conductivities and low electrical resistivities, such as copper, aluminum, graphite, and arrays of carbon nanotubes, etc.

Numerical ranges disclosed in the present application include, but are not limited to, ranges of temperatures, ranges of pressures, ranges of molecular weights, ranges of integers, ranges of conductance and resistance values, ranges of times, and ranges of thicknesses. The disclosed ranges of any type, disclose individually each possible number that such a range could reasonably encompass, as well as any sub-ranges and combinations of sub-ranges encompassed therein. For example, disclosure of a pressure range is intended to disclose individually every possible pressure value that such a range could encompass, consistent with the disclosure herein.

Use of the term “about” is intended to describe values either above or below the stated value, which the term “about” modifies, in a range of approx. +/−10%; in other instances the values may range in value either above or below the stated value in a range of approx. +/−5%. When the term “about” is used before a range of numbers (i.e., about 1-5) or before a series of numbers (i.e., about 1, 2, 3, 4, etc.) it is intended to modify both ends of the range of numbers or each of the numbers in the series, unless specified otherwise.

### II. Gap Filler or Gap Pads

The gap pads and gap fillers having independently tunable mechanical and thermal and/or electrical properties described include at least one compressible and/or compliant core component and at least one layer of a heat transporting and/or electrically conducting material wrapping the at least one compressible and/or compliant core component.

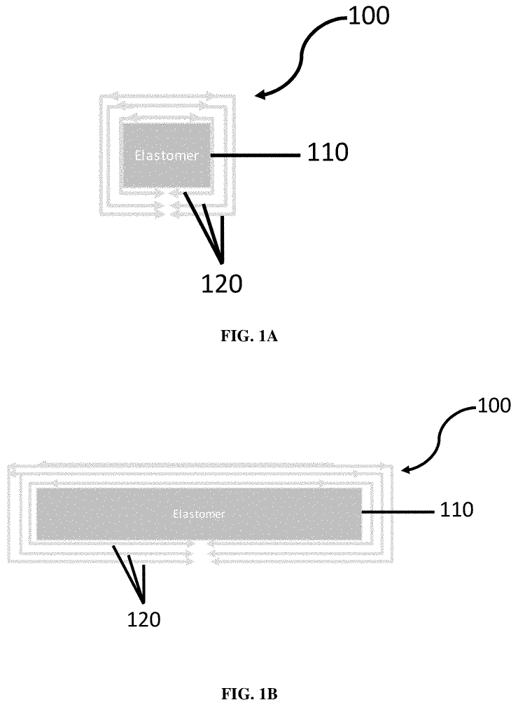

As shown in FIG. 1A, a short-length gap filler or gap pad 100 has a a compressible and/or compliant core component 110 formed of an elastomer and can include three layers of a heat transporting and/or electrically conducting material 120 wrapped around component 110. FIG. 1B shows a longer length gap filler or gap pad 100, as compared to FIG. 1A, having a compressible and/or compliant core component 110 formed of an elastomer and three layers of a heat transporting and/or electrically conducting material 120 wrapped around component 110. Lastly, FIG. 1C demonstrates a gap pad or filler 100 formed from multiple core components 110 (i.e., three) each formed of an elastomer, which are aligned in a linear array, and three layers of a heat transporting and/or electrically conducting material 120 wrapped around each of the three 110 components. The inclusion of more than one core component 110 each wrapped in material 120 can be beneficial as it provides more pathways for heat and/or electrical transport through the gap pad or filler. By decreasing feature sizes of the wrapped core components in such multi-component systems the number of thermal/electrically conductive elements (compare FIGS. 1B and 1C, for example) can be increased per unit area in the direction of heat and/or electrical energy transport.

In certain instances, the compressible and/or compliant core component comprised of or is formed from an elastomer, a spring, a sponge, a foam, or a combination thereof. In some cases, the compressible and/or compliant core component is in bar, sheet, or roll form, or a combination thereof. Exemplary elastomers can be selected from, without limitation, silicone rubbers, natural rubbers, nitrile rubber, fluoropolymer elastomers, polyurethanes, ethylene propylene diene terpolymer (EPDM), styrene-butadiene rubber (SBR), neoprene, polyamide elastomers, and combinations thereof. In certain instances, however, the compressible and/or compliant core component may free or substantially free of silicone (“substantially free,” refers to less than 5%, 4%, 3%, 2%, 1%, 0.9%, 0.8%, 0.7%, 0.6%, 0.5%, 0.4%, 0.3%, 0.2%, 0.1%, or less).

In some instances where the compressible and/or compliant core component is a spring it may be selected from a compression spring, a disc spring, a coned-disc spring, or a leaf spring which can be made of a metal, plastic, or rubber. In certain instances where the compressible and/or compliant core is a sponge or a foam these may be made, for example, of a metal, plastic, or rubber. The sponge or foam may include a lattice or cellular structure. In certain instances, the sponge or foam may be fabricated via injection molding or 3-D printing.

The compressible and/or compliant core component(s) may be formed or obtained to have any dimension needed. Methods of preparing and forming compressible and/or compliant core components from such materials as described above and having requisite dimensions needed for forming a core component for a gap pad or filler described herein are known.

The compressible and/or compliant core component typically has a hardness in a range of between about Shore A00-A50.

The compressible and/or compliant core component typically demonstrate a deflection of at least 25% or less when exposed pressure of less than about 100 psi, 90 psi, 80 psi, 70 psi, 60 psi, 50 psi, 40 psi, 30 psi, 20 psi, 15 psi, 10 psi, or 5 psi. The compressible and/or compliant core component may also demonstrate a deflection of at least 10% or greater when exposed pressure of less than about 100 psi, 90 psi, 80 psi, 70 psi, 60 psi, 50 psi, 40 psi, 30 psi, 20 psi, 15 psi, 10 psi, or 5 psi. In some instances, the compressible and/or compliant core component demonstrates a deflection of at least 100 microns or greater when exposed to a pressure of less than about 100 psi, 90 psi, 80 psi, 70 psi, 60 psi, 50 psi, 40 psi, 30 psi, 20 psi, 15 psi, 10 psi, or 5 psi. Such deflection properties are typically retained in the final gap pad or filler formed from the wrapped core component.

The compressible and/or compliant core component typically produces no outgassing or low outgassing (“low,” refers to negligible amounts of outgassing).

The compressible and/or compliant core component typically has a compression set of less than about 25%, 20%, 15%, 10%, or 5% at 150° C., or 70° C., preferably less than about 10% at 70° C. The compressible and/or compliant core component preferably has a compression set of less than about 25%, 20%, 15%, 10%, or 5% at 150° C., or 70° C., preferably less than about 10% at 150° C. Such compression set properties are typically retained in the final gap pad or filler formed from the wrapped core component.

The gap fillers or pads described demonstrate elastic recovery properties following one or more repeated deformations, typically compressions, at varying pressures up to about 50, 100, 200, 300, 400, 500 psi, or greater. Elastic recovery of the gap fillers or pads, expressed as a percentage value, following one or more compressions can be greater than about 50%, 60%, 70%, 80%, 90%, 91%, 92%, 93%, 94%, 95%, 96%, 97%, 98%, or 99%. In some instances, the gap fillers or pads described also demonstrate compression set properties following one or more repeated deformations, typically compressions, at varying pressures up to about 50, 100, 200, 300, 400, 500 psi, or greater. Compression set of the gap fillers or pads, expressed as a percentage value, following one or more compressions can be less than about 20%, 15%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, or 0.1%.

The compressible and/or compliant core component is typically heat resistant up to a temperature 100° C., 125° C., 150° C., 175° C., or 250° C., while retaining compressibility, elastic recovery, and compliance. In some instances the compressible and/or compliant core component is additionally or alternatively cold resistant down to a temperature of −10° C., −40° C., −55° C., −75° C., −160° C., −190° C., while retaining compressibility, elastic recovery, and compliance. Such temperature resistance properties are typically retained in the final gap pad or filler formed from the wrapped core component.

The heat transporting and/or electrically conducting material which wrap around the core component can be a flexible foil or sheet or a flexible laminate material. The heat transporting and/or electrically conducting material layer can be a flexible foil or sheet of a metal or a metal alloy; or a flexible graphite or synthetic graphite sheet; or a flexible laminate material which is formed of a carbon-based material which optionally further includes a foil or a foil comprising an array of carbon nanotubes. Arrays of carbon nanotubes on foil, such as made of metal, are known. Methods of preparing such CNT arrays which may be single or multitiered are described in U.S. Publication No. 2018/0254236 A1. The metal from which the heat transporting and/or electrically conducting material is formed from can be copper or aluminum, amongst other metals and alloys thereof which have good thermal conductivities and/or electrical conductivities.

Exemplary carbon-based material which may be or form part of the heat transporting and/or electrically conducting material include, without limitation, graphitic carbon selected from graphite, single or multilayer graphene, reduced graphene oxide, carbon nanotubes, and combinations thereof.

For the gap fillers or gap pads the heat transporting and/or electrically conducting material typically has a thermal conductivity in the range of between about 1-2500 W/m·K, 1-2000 W/m·K, 1-1500 W/m·K, 1-1000 W/m·K, 1-500 W/m·K, 5-500 W/m·K, 5-400 W/m·K, 5-300 W/m·K, 5-200 W/m·K, 5-150 W/m·K, or 5-100 W/m·K. In some instances, a thermal conductivity of 100-1900 W/m·K is preferred. The presence of the heat transporting and/or electrically conducting material provides increased thermal conductivity of at least about 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, 20 times, 21 times, 22 times, 23 times, 24 times, 25 times, 50 times, 100 times, or greater, as compared to the thermal conductivity of a gap filler or gap pad excluding a heat transporting and/or electrically conducting material present thereon.

The thermal contact resistance of the gap pads or gap fillers is typically reduced by at least about 25%, 30%, 35%, 40%, 45%, 50%, 55%, 60%, 65%, 70% or greater when the gap pads or gap fillers include a heat transporting and/or electrically conducting material, when measured, for example, using transient structure function analysis. In certain embodiments, the gap pads or gap fillers exhibit thermal resistances of less than about 2.0, 1.5, 1.0, 0.9, 0.8, 0.7, 0.6, 0.5, 0.4, 0.3, 0.2, or 0.1 cm² K/W, as compared to gap pads or gap fillers without the inclusion of a heat transporting and/or electrically conducting material wrapped around the core component(s).

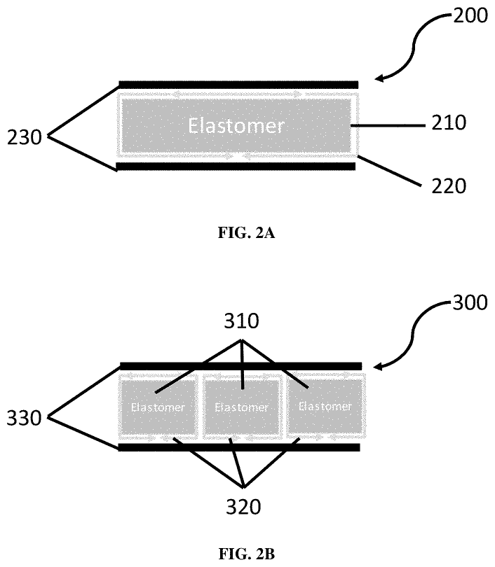

The primary direction of heat flow, when the gap pads or fillers are placed between a heat source and a sink, is associated with the heat transporting and/or electrically conducting material which is wrapped around the core component. For example, FIGS. 3A-3C show heat flow from a heat source through the gap pad or filler to a heat sink via the heat transporting and/or electrically conducting material. In some instances, the primary direction of heat flow is associated and/or controlled by the heat transporting and/or electrically conducting material which is wrapped around the core component. It is believed that thermal energy is transported only or substantially only (“substantially only,” as used here refers to greater than 90%, 91%, 92%, 93%, 94% c, 95%, 96%, 97%, 98%, 99%, 99.1%, 99.2%, 99.3%, 99.4%, 99.5%, 99.5%, 99.6%, 99.7%, 99.8%, or 99.9%) by the heat transporting and/or electrically conducting material and not by the at least one compressible and/or compliant core component, which may have limited to no thermal transporting properties. It is believed that thermal transport through only the heat transporting and/or electrically conducting material (i.e., the foil as opposed to both the foil and the elastomer) may reduce the RC time constant (thermal response time) of the system which includes the gap filler or pad.

In instances, the heat transporting and/or electrically conducting material has an electrical resistance of less than about 1000, 900, 800, 700, 600, 500, 400, 300, 200, 100, 75, 50, 25, 20, 15, 10, 9, 8, 7, 6, 5, 4, 3, 2, 1, 0.9, 0.8, 0.7, 0.6, 0.5, 0.4, 0.3, 0.2, or 0.1 milliohms. The inclusion of the heat transporting and/or electrically conducting material provides increased electrical conductivity of at least about 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, 20 times, 21 times, 22 times, 23 times, 24 times, 25 times, 50 times, 100 times, 1000 times, or greater, as compared to the electrical conductivity of a gap filler or gap pad excluding a heat transporting and/or electrically conducting material present thereon.

The primary direction of electrical energy flow, when the gap pads or fillers are placed between electrical components, is associated with the heat transporting and/or electrically conducting material which is wrapped around the core component. In some instances, the primary direction of electrical flow direction is associated and/or controlled by the heat transporting and/or electrically conducting material which is wrapped around the core component. It is believed that electrical energy is transported only or substantially only (“substantially only,” as used here refers to greater than 90%, 91%, 92%, 93%, 94%, 95%, 96%, 97%, 98%, 99%, 99.1%, 99.2%, 99.3%, 99.4%, 99.5%, 99.5%, 99.6%, 99.7%, 99.8%, or 99.9%) only by the heat transporting and/or electrically conducting material and not by the at least one compressible and/or compliant core component, which may have limited to no electrical energy transporting properties.

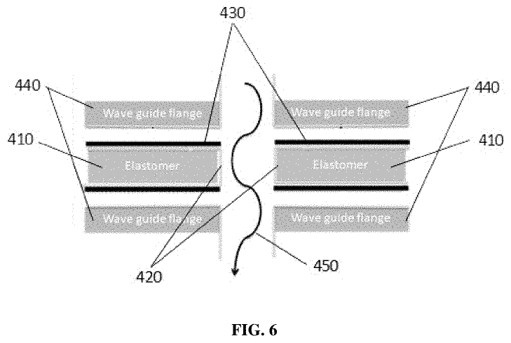

In some instances, the electrical conductivity of the heat transporting and/or electrically conducting material, which is wrapped around the core component(s), can serve as an electrical shield. In these instances, the heat transporting and/or electrically conducting material can prevent and/or block all or substantially all of the transmission of electromagnetic waves through or normal to the surface of the heat transporting and/or electrically conducting material (“substantially all” refers to preventing/blocking at least about 95%, 97%, 98%, 99%, 99.9%, or greater of the transmission of electromagnetic waves, as compared to in the absence of the transporting and/or electrically conducting material). As shown in the non-limiting illustration in FIG. 6, in some applications, gap pad or gap filler(s), as described herein, may be placed between two flanges of a waveguide to accommodate misalignment or out of flatness between the two waveguide flanges. In this instance, the heat transporting and/or electrically conducting layer prevents loss or unwanted reflections from the waveguide joint. This may be measured through scattering parameter (S-parameter testing) testing, using art known techniques. In an S-parameter test, the waveguide joint may see a return loss of greater than 20 dB, or preferably greater 30 dB, 40 dB, or 50 dB. In another instance, the waveguide joint may see an insertion loss of less than 0.5 dB, 0.4 dB, 0.3 dB, 0.2 dB, or 0.1 dB during S-parameter testing.

The heat transporting and/or electrically conducting material which is wrapped around the core component(s) may be placed such that gaps or seams are minimized and sufficiently small in order to minimize losses at the seams. The heat transporting and/or electrically conducting materials and interfacing materials wrapped around the core component may be placed such that there are no seams or minimal number of seams or material transitions in the path of a transmitted electromagnetic wave. The wrapping layers of the heat transporting and/or electrically conducting material may be wrapped such that the material overlaps itself, covering any seams created by the initial wrapping with the material by inclusion of a second or third wrap, or greater. The interfacing material layer may be placed such that there is a recess between the edge of the interfacing material layer and the edge of the signal path, to avoid placing a material transition in the path of a transmitted signal in, for example, a waveguide. Minimizing the presence of seams or material transitions in the signal path will reduce the potential for passive intermodulation inside the waveguide.

The gap fillers or gap pads can include multiple core components, such as two, three, four, five, six, seven, eight, nine, ten, or more of the compressible and/or compliant core components per square inch of the gap filler or gap pad.

The heat transporting and/or electrically conducting material typically wraps at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, or 99.9%, of the surface of the compressible and/or compliant core component(s). In certain instances, all of the surface(s) of one or more compressible and/or compliant core component(s) of a gap pad or filler are wrapped by the heat transporting and/or electrically conducting material. In some cases, the heat transporting and/or electrically conducting material wraps substantially all of the surface of the at least one compressible and/or compliant core component (“substantially all,” as used here refers to greater than 90%, 91%, 92%, 93%, 94%, 95%, 96%, 97%, 98%, 99%, 99.1%, 99.2%, 99.3%, 99.4%, 99.5%, 99.5%, 99.6%, 99.7%, 99.8%, or 99.9%).

In some instances there is only one layer of heat transporting and/or electrically conducting material wrapped around one or more core component(s). In some other cases there may be multiple layers wrapped around the core component(s), such as two, three, four, five, six, seven, eight, nine, or more layers of the at least one layer of a heat transporting and/or electrically conducting material. For example, there may be three or six layers of the heat transporting and/or electrically conducting material wrapped around core component(s) in certain non-limiting examples of gap pads or fillers.

Multiple layers of the heat transporting and/or electrically conducting material may be concentrically wrapped around the at least one compressible and/or compliant core component. In other instances, the heat transporting and/or electrically conducting material may be wrapped in a serpentine manner. In certain cases, where there are multiple compressible and/or compliant core components each component can be independently wrapped by the heat transporting and/or electrically conducting material or they may all together be wrapped by one or more layers of the heat transporting and/or electrically conducting material.

The heat transporting and/or electrically conducting material, which may be a foil, sheet, or laminate, typically has a thickness in a range of between about 0 μm to 250 μm, preferably between 17 μm to 100 μm. The size of the heat transporting and/or electrically conducting material needed to wrap one or more core components can be determined as needed. For example, a sufficient size of a foil, sheet, or laminate of heat transporting and/or electrically conducting material can be formed or obtained needed to wrap the compressible/compliant core components, as needed.

The layer of a heat transporting and/or electrically conducting material is typically in the form of a flexible foil or sheet; or a flexible laminate material which resists tearing, cracking, and/or creasing.

In some cases, the heat transporting and/or electrically conducting material is adhesive or comprises an adhesive and is bonded to all or substantially all of the surface of the at least one compressible and/or compliant core component(s). The adhesive may be selected from a hot glue or a hot melt adhesive that combines wax, tackifiers and a polymer base to provide improved adhesion properties to one or more surfaces. In some embodiments, the adhesive is a pressure sensitive adhesive. In certain other embodiments, the adhesive is a monomer that polymerizes upon contact with air or water, such as a cyanoacrylate. In yet other embodiments, the adhesive is a combination of a pressure sensitive adhesive and a thermally activated (or activatable) adhesive polymers which enhances ease of adhesion of the coatings to a surface(s), by way of the pressure sensitive adhesive and additional and more permanent or semi-permanent adhesion by way of the thermal adhesive. In some embodiments, the adhesive is an epoxy adhesive. Adhesive coatings of any form can also be removable (such as by peeling).

The gap filler or gap pads described above may further include: an interfacing material present on at least one surface of the heat transporting and/or electrically conducting material surrounding the at least one compressible and/or compliant core component. The interfacing material may be present on specific surfaces of the gap filler or pad. For example, when the gap filler or pad is placed between a heat source and a sink the interfacing material may be present only on the surfaces of the gap pad or filler that are in direct contact with the surface(s) of the heat source and the sink. The interfacing material may be wrapped around all or substantially all of the heat transporting and/or electrically conducting material's surface (“substantially all,” as used here refers to greater than 90%, 91%, 92%, 93%, 94%, 95%, 96%, 97%, 98%, 99%, 99.1%, 99.2%, 99.3%, 99.4%, 99.5%, 99.5%, 99.6%, 99.7%, 99.8%, or 99.9%).

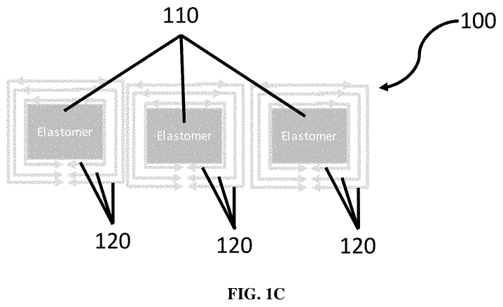

As shown in illustrative FIG. 2A, a gap filler or gap pad 200 having a compressible and/or compliant core component 210 formed of an elastomer and a layer of a heat transporting and/or electrically conducting material 220 wrapped around component 210 and the gap pad or filler is in at least partial contact (i.e., contacted or wrapped) with an interfacing material 230. FIG. 2B shows a multiple core component containing gap filler or gap pad 300 having three compressible and/or compliant core components 310 formed of an elastomer, which are aligned in a linear array (other 3-D arrangements, such as stacked core components, can be used as well), and a layer of a heat transporting and/or electrically conducting material 320 wrapped around each of the three 310 components where the gap pad or filler is in at least partial contact (i.e., wrapped) with an interfacing material 330. FIGS. 2A and 2B show an example where only top and bottom surfaces of the gap filler or pad are contacted with an interfacing material and where the two interfacing material coated surfaces may each be contacted to a heat source or a sink, respectively.

The interfacing material may be formed of or comprised of a carbon nanotube array optionally comprising a metal substrate or a graphite or carbon-based material. The interfacing material may be in the form of a foil, a laminate, sheet, thermal pad, or thermal tape. In some instances, the interfacing material may be an array of carbon nanotubes on substrate, such as a metal foil. Arrays of carbon nanotubes on foil, such as made of metal, are known. Methods of preparing such CNT arrays which may be single or multitiered are described in U.S. Publication No. 2018/0254236 A1.

In some instances, two, three, four, five, six, seven, eight, nine, ten, or more of the compressible and/or compliant core components are each wrapped by the heat transporting and/or electrically conducting material and the interfacing material acts as a heat spreader or coupler between the wrapped compressible and/or compliant core components.

In some cases, the interfacing material is adhesive or comprises an adhesive. The adhesive may be selected from a hot glue or a hot melt adhesive that combines wax, tackifiers, and a polymer base to provide improved adhesion properties to one or more surfaces. In some embodiments, the adhesive is a pressure sensitive adhesive. In certain other embodiments, the adhesive is a monomer that polymerizes upon contact with air or water, such as a cyanoacrylate. In yet other embodiments, the adhesive is a combination of a pressure sensitive adhesive and a thermally activated (or activatable) adhesive polymers which enhances ease of adhesion of the coatings to a surface(s), by way of the pressure sensitive adhesive and additional and more permanent or semi-permanent adhesion by way of the thermal adhesive. In some embodiments, the adhesive is an epoxy adhesive. Adhesive coatings of any form can also be removable (such as by peeling).

It is believed that the interfacing material improves surface contact between the gap filler or gap pad and two or more surfaces when the gap filler or gap pad is placed in between the two or more surfaces.

The interfacing material can have a thermal conductivity in the range of between about 1-2500 W/m·K, 1-2000 W/m·K, 1-1500 W/m·K, 1-1000 W/m·K, 1-500 W/m·K, 5-500 W/m·K, 5-400 W/m·K, 5-300 W/m·K, 5-200 W/m·K, 5-150 W/m·K, or 5-100 W/m·K. In some instances, a thermal conductivity of 100-1900 W/m·K is preferred.

The interfacing material may be a foil, sheet, or laminate, typically having a thickness in a range of between about 10-250 μm. The size of the interfacing material needed to wrap one or more core components can be determined as needed. For example, a sufficient size of a foil, sheet, or laminate of heat transporting and/or electrically conducting material can be formed or obtained needed to wrap the whole surface or a portion thereof (i.e., one side, two sides, etc.) of the heat transporting and/or electrically conducting material, as needed.

The layer of interfacing material is typically in the form of a flexible foil or sheet; or a flexible laminate material which resists tearing, cracking, and/or creasing.

The gap pads or gap fillers described herein can be conformable and flexible. The gap pads or gap fillers can conform to a device's dimensions, and elastically deform or deflect under installation force. The gap pads or gap fillers can conform to flat, non-flat, undulating, or other uniform or non-uniform surface shapes and provide a good thermal interface independent of a heat-generating device's surface flatness. In most instances, the gap pads or gap fillers conform to contact all of the desired surface, such as of a heat sink or a heat generating source/device, which is to be contacted with the gap pads or gap fillers or substantially all of the surface (i.e., “substantially all,” refers to at least about 90%, 91%, 92%, 93%, 94%, 95%, 96%, 97%, 98%, or 99%, or higher). In some instances, the gap pads or gap fillers can conform to contact multiple devices or components thereof within the same substrate or system.

The gap pads or gap fillers preferably conform to contact all of the desired surface of a heat generating source, such as a device, which is to be contacted with the gap pads or gap fillers or substantially all of the surface desired and traps no or a minimum amount of air or voids and provides intimate contact between the surface interfaces contacted by the gap pads or gap fillers. The flexible and conformable gap pads or gap fillers conform to heat-generating surfaces and minimize gaps. Flexibility and conformability allow for the gap pads or gap fillers to be flattened or smoothed, as needed, to mate well or completely to the surface(s) of a heat-generating source or heat sink, or the like.

The gap pads or gap fillers allow for a bending to a radius of less than about 30 cm, less than about 10 cm, less than about 5 cm, 1 cm, 5 mm, 1 mm, 0.5 mm, or even lower at room temperature without significantly adversely affecting the function or energy transport efficiency of the gap pads or gap fillers. That is, the gap pads or gap fillers do not crack, kink, or significantly plastically deform to a shape that may leave a gap between the gap pads or gap fillers and surface(s) of a heat generating source or other devices or substrates thereof.

The flexibility and compressibility of the core component of the flexible and conformable gap pads or gap fillers allow bending or flexing, deflecting, and/or absorbing forces (e.g., impact force, shock force, vibration force with variable energy and duration). In some instances, the gap pads or gap fillers can act as a vibration damper or shock isolator to the heat generating source and/or heat sink to which it forms an interface between.

### III. Methods of Manufacturing Gap Fillers or Gap Pads

The gap fillers or gap pads described herein may be formed according to a method as follows.

A non-limiting exemplary method of forming a gap pad or gap filler includes the steps of:

(a) providing at least one compressible and/or compliant core component; and at least one heat transporting and/or electrically conducting material; and

(b) wrapping the at least one heat transporting and/or electrically conducting material around the at least one compressible and/or compliant core component; and

wherein step (b) optionally includes applying an adhesive to the at least one heat transporting and/or electrically conducting material to maintain the position of the wrapped at least one heat transporting and/or electrically conducting material on the compressible core.

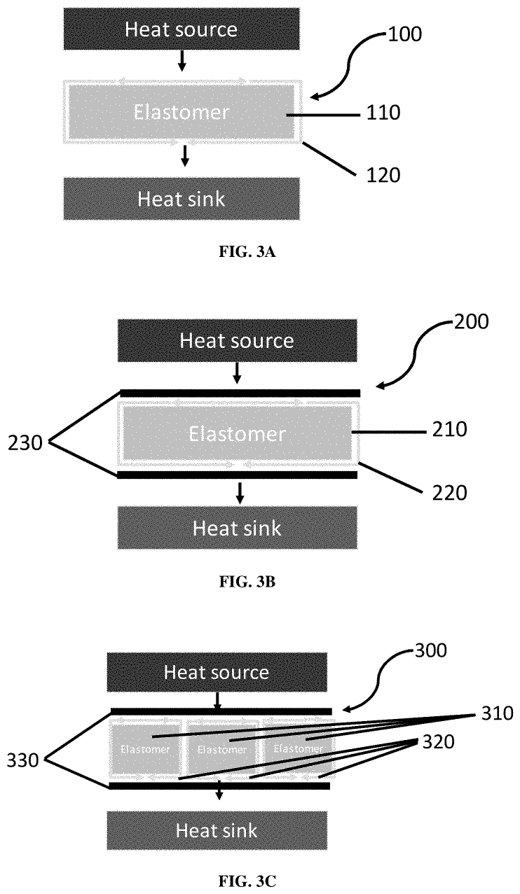

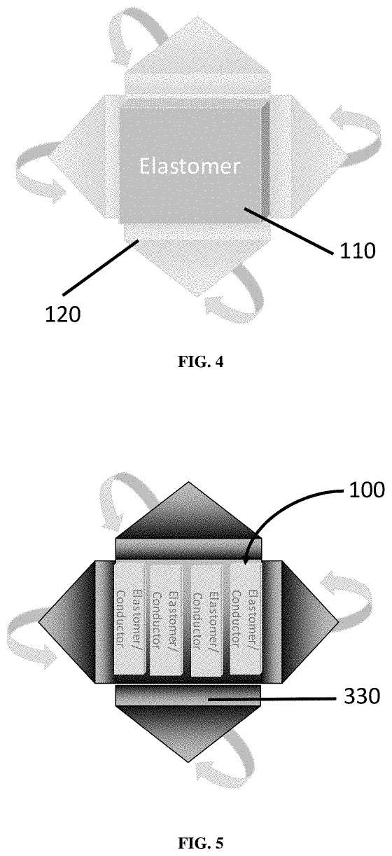

As shown in FIG. 4, a method can include wrapping a compressible and/or compliant core component 110 formed of an elastomer with a layer of a heat transporting and/or electrically conducting material 120. The arrows shown in the figure are illustrative of the wrapping action of component 110 with material 120. FIG. 5 also shows an illustrative method of wrapping four gap pads or fillers 100 (each formed of an elastomer wrapped with a heat transporting and/or electrically conducting material) and wrapped with interfacing material 330. The arrows shown in the figure are illustrative of the wrapping of the four gap fillers or pads, 110, with material 330.

In certain instances, the compressible and/or compliant core component comprised of or is formed from an elastomer, a spring, a sponge, a foam, or a combination thereof. In some cases, the compressible and/or compliant core component is in bar, sheet, or roll form, or a combination thereof. Exemplary elastomers can be selected from, without limitation, silicone rubbers, natural rubbers, nitrile rubber, fluoropolymer elastomers, polyurethanes, ethylene propylene diene terpolymer (EPDM), styrene-butadiene rubber (SBR), neoprene, polyamide elastomers, and combinations thereof. In certain instances, however, the compressible and/or compliant core component may free or substantially free of silicone (“substantially free,” refers to less than 5%, 4%, 3%, 2%, 1%, 0.9%, 0.8%, 0.7%, 0.6%, 0.5%, 0.4%, 0.3%, 0.2%, 0.1%, or less).

In instances where the compressible and/or compliant core component is a spring it may be selected from a compression spring, a disc spring, a coned-disc spring, or a leaf spring which can be made of a metal, plastic, or rubber. In instances where the compressible and/or compliant core is a sponge or a foam these may be made, for example, of a metal, plastic, or rubber. The sponge or foam may include a lattice or cellular structure. In certain instances, the sponge or foam may be fabricated via injection molding or 3-D printing.

The compressible and/or compliant core component(s) may be formed or obtained to have any dimension needed. Methods of preparing and forming compressible and/or compliant core components from such materials as described above and having requisite dimensions needed for forming a core component for a gap pad or filler described herein are known.

The compressible and/or compliant core component typically has a hardness in a range of between Shore A00-A50.

The heat transporting and/or electrically conducting material which wrap around the core component can be a flexible foil or sheet or a flexible laminate material. The heat transporting and/or electrically conducting material layer can be a flexible foil or sheet of a metal or a metal alloy; or a flexible graphite or synthetic graphite sheet; or a flexible laminate material which is formed of a carbon-based material which optionally further includes a foil or a foil comprising an array of carbon nanotubes. Arrays of carbon nanotubes on foil, such as made of metal, are known. Methods of preparing such CNT arrays which may be single or multitiered are described in U.S. Publication No. 2018/0254236 A1. The metal from which the heat transporting and/or electrically conducting material is formed from can be copper or aluminum, amongst other metals and alloys thereof which have good thermal conductivities and/or electrical conductivities.

Exemplary carbon-based material which may be or form part of the heat transporting and/or electrically conducting material include, without limitation, graphitic carbon selected from graphite, single or multilayer graphene, reduced graphene oxide, carbon nanotubes, and combinations thereof.

The methods described can be used to prepare gap pads or fillers having at least one core component. In some instances, two, three, four, five, six, seven, eight, nine, ten, or more of the compressible and/or compliant core components can be used per square inch of the gap filler or gap pad. When more than three core components are present these may be arranged in a linear array (see FIG. 1C) or may be stacked in a 3-dimensional pattern, as needed. Typically the heat transporting and/or electrically conducting material wraps at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, or 99.9%, of the surface of the at least one compressible and/or compliant core component. The heat transporting and/or electrically conducting material can also wrap all or wrap substantially all of the surface of the at least one compressible and/or compliant core component surface (“substantially all,” as used here refers to greater than 90%, 91%, 92%, 93%, 94%, 95%, 96%, 97%, 98%, 99%, 99.1%, 99.2%, 99.3%, 99.4%, 99.5%, 99.5%, 99.6%, 99.7%, 99.8%, or 99.9%).

The methods described can be used to prepare gap pads or fillers having at least one layer of heat transporting and/or electrically conducting material wrapping one or more core components. In some instances, there are two, three, four, five, six, seven, eight, nine, or more layers of the at least one layer of a heat transporting and/or electrically conducting material.

Multiple layers of the heat transporting and/or electrically conducting material may be concentrically wrapped around the at least one compressible and/or compliant core component. In other instances, the heat transporting and/or electrically conducting material may be wrapped in a serpentine manner. In certain cases, where there are multiple compressible and/or compliant core components each component can be independently wrapped by the heat transporting and/or electrically conducting material or they may all together be wrapped by one or more layers of the heat transporting and/or electrically conducting material.

Wrapping of the one or more heat transporting and/or electrically conducting material layers can be carried out on multiple edges of a core component (i.e., elastomer) to increase density of conductive elements i.e. spreading around 4 edges instead of two. Symmetry along seams means negligible impact to energy transfer, as energy does not cross lines of symmetry. Alternating placement of seams between successive layers of heat transporting and/or electrically conducting material can make both contact surfaces seamless. Seams, when wrapping with the material, may also be placed on vertical edges of the gap filler or pad so that both energy transfer surfaces are seamless. In some instances, the method may include cutting a hole(s) in wrapping heat transporting and/or electrically conducting material, prior to wrapping, such that they align with one another after wrapping to simplify the addition of bolt holes or other features. Lastly, the method may include a further step of cutting one or more holes, as needed, in the finished gap filler or pad.

The heat transporting and/or electrically conducting material, which may be a foil, sheet, or laminate, typically has a thickness in a range of between about 0 μm to 250 μm, preferably between 17 μm to 100 μm. The size of the heat transporting and/or electrically conducting material needed to wrap one or more core components can be determined as needed. For example, a sufficient size of a foil, sheet, or laminate of heat transporting and/or electrically conducting material can be formed or obtained needed to wrap the compressible/compliant core components, as needed.

In some cases, the heat transporting and/or electrically conducting material used in the methods of preparing gap pads or fillers are adhesive or comprise an adhesive which can be bonded to all or substantially all of the surface of the at least one compressible and/or compliant core component(s). The adhesive may be selected from a hot glue or a hot melt adhesive that combines wax, tackifiers and a polymer base to provide improved adhesion properties to one or more surfaces. In some embodiments, the adhesive is a pressure sensitive adhesive. In certain other embodiments, the adhesive is a monomer that polymerizes upon contact with air or water, such as a cyanoacrylate. In yet other embodiments, the adhesive is a combination of a pressure sensitive adhesive and a thermally activated (or activatable) adhesive polymers which enhances ease of adhesion of the coatings to a surface(s), by way of the pressure sensitive adhesive and additional and more permanent or semi-permanent adhesion by way of the thermal adhesive. In some embodiments, the adhesive is an epoxy adhesive. Adhesive coatings of any form can also be removable (such as by peeling).

The methods described above can include further steps of:

(c) providing an interfacing material; and

(d) contacting the interfacing material to at least one surface of the heat transporting and/or electrically conducting material wrapped around the at least one compressible and/or compliant core component.

The interfacing material may be formed of or comprised of a carbon nanotube array optionally comprising a metal substrate or a graphite or carbon-based material. The interfacing material may be in the form of a foil, a laminate, sheet, thermal pad, or thermal tape. In some instances, the interfacing material may be an array of carbon nanotubes on substrate, such as a metal foil. Arrays of carbon nanotubes on foil, such as made of metal, are known. Methods of preparing such CNT arrays which may be single or multitiered are described in U.S. Publication No. 2018/0254236 A1.

In some instances, two, three, four, five, six, seven, eight, nine, ten, or more of the compressible and/or compliant core components are each wrapped by the heat transporting and/or electrically conducting material and the interfacing material acts as a heat spreader or coupler between the wrapped compressible and/or compliant core components.

In some cases, the interfacing material is adhesive or comprises an adhesive. The adhesive may be selected from a hot glue or a hot melt adhesive that combines wax, tackifiers and a polymer base to provide improved adhesion properties to one or more surfaces. In some embodiments, the adhesive is a pressure sensitive adhesive. In certain other embodiments, the adhesive is a monomer that polymerizes upon contact with air or water, such as a cyanoacrylate. In yet other embodiments, the adhesive is a combination of a pressure sensitive adhesive and a thermally activated (or activatable) adhesive polymers which enhances ease of adhesion of the coatings to a surface(s), by way of the pressure sensitive adhesive and additional and more permanent or semi-permanent adhesion by way of the thermal adhesive. In some embodiments, the adhesive is an epoxy adhesive. Adhesive coatings of any form can also be removable (such as by peeling).

The interfacing material can have a thermal conductivity in the range of between about 1-2500 W/m·K, 1-2000 W/m·K, 1-1500 W/m·K, 1-1000 W/m·K, 1-500 W/m·K, 5-500 W/m·K, 5-400 W/m·K, 5-300 W/m·K, 5-200 W/m·K, 5-150 W/m·K, or 5-100 W/m·K. In some instances, a thermal conductivity of 100-1900 W/m·K is preferred.

The interfacing material may be a foil, sheet, or laminate, typically having a thickness in a range of between about 10-250 μm. The size of the interfacing material needed to wrap one or more core components can be determined as needed. For example, a sufficient size of a foil, sheet, or laminate of heat transporting and/or electrically conducting material can be formed or obtained needed to wrap the whole surface or a portion thereof (i.e., one side, two sides, etc.) of the heat transporting and/or electrically conducting material, as needed.

The layer of interfacing material is typically in the form of a flexible foil or sheet; or a flexible laminate material which resists tearing, cracking, and/or creasing.

The gap filler or pads formed according to the methods noted herein can have any suitable dimensions needed to cover and/or contact one or more surfaces of a heat-generating device (such as a computer chip or component) or to cover and/or contact one or more surfaces of a heat sink.

### IV. Gap Filler or Gap Pad Applications

The gap fillers or gap pads described herein are well suited for applications where they are interfacing a heat sink and heat generating source and can conform to sources of such heat sinks or heat generating devices, such as computer chips, computer modules, multi-component system, electronic devices (i.e., displays), etc. Such heat generating sources typically demonstrate non-planarity where such non-planarity may be a result of warpage or curvature due to manufacture or manufacturing tolerances, thermal expansion during use, or mechanical stress/strain during assembly or use.

The gap fillers or gap pads can be placed between a heat generating source (i.e., a device) and a heat sink. For example, FIG. 3A shows a gap filler or gap pad 100 which has a compressible and/or compliant core component 110 formed of an elastomer and a layer of a heat transporting and/or electrically conducting material 120 wrapped around component 110. The arrows illustrate the direction of heat flow from the heat source to the heat sink via gap filler or gap pad 100. FIG. 3B also shows a gap filler or gap pad 200 having a compressible and/or compliant core component 210 formed of an elastomer and a layer of a heat transporting and/or electrically conducting material 220 wrapped around component 210 and which is at least in partial contact (i.e., wrapped) with an interfacing material 230. Again, the arrows depict the direction of heat flow from the heat source to the heat sink via gap filler or gap pad 200. Lastly, FIG. 3C is yet another illustration of a multi-component gap filler or gap pad 300 having three compressible and/or compliant core components 310 formed of an elastomer, which are aligned in a linear array, and a layer of a heat transporting and/or electrically conducting material 320 wrapped around each of the three 310 components and which is at least in partial contact (i.e., wrapped) with an interfacing material 330. The arrows depict the direction of heat flow from the heat source to the heat sink via gap filler or gap pad 300.

The gap pad or gap filler can be used to accommodate differences in height between multiple components which are located on a same substrate. The gap pad or gap filler can also be used to accommodate differences in height between multiple components of different heights interfacing with a single planar secondary surface, such as a heat sink. The gap pad or gap filler can also be used to accommodate or fill a curvature of a first surface to improve contact with a second surface with a different curvature. In yet another example, the gap pad or gap filler can be used to accommodate manufacturing tolerances of a part that is otherwise not made to precise or tightly controlled flatness. In another exemplary use, a device includes the gap pad or gap filler which is on a pedestal, used for temperature control, and the pad or filler shows less than 15% compression set after 10, 100, 1000, 10000, 100,000 or 1 million insertion or device engagement cycles.

The flexible and conformable gap fillers or gap pads allow for intimate contact between surface(s) of heat generating devices or sources, as the surfaces may be curved, bent, bowed, or be otherwise deformed by design or due to thermal expansion(s) of the devices or sources.

The gap fillers or gap pads may be used in node multi-chip modules (MCMs). The flexible and conformable gap fillers or gap pads allow for uniform or essentially uniform contact with MCMs. Accordingly, the gap fillers or gap pads are particularly suitable for such applications because they can be readily adjusted, if needed, to meet the tolerances required for such applications. As microchips heat up, they can warp leading to a center to-edge warpage greater than 50 μm whereas in multichip applications, the gap fillers or gap pads can accommodate chip-to-chip offsets of 100 μm or more and/or can also accommodate chip center-to-edge warpages of greater than 50 μm.

The gap fillers or gap pads can be used in the manufacture of personal computers and components thereof, server computers and components thereof, memory modules, graphics chips, radar and radio-frequency (RF) devices, disc drives, displays, including light-emitting diode (LED) displays, lighting systems, pipes, automotive control units, power-electronics, solar cells, batteries, communications equipment, such as cellular phones, thermoelectric generators, and imaging equipment, including MRIs.

The gap fillers or gap pads may be attached to sources of waste heat such as hot pipes for temperature control or energy extraction. The gap fillers or gap pads can be abutted or adhered to a heat generating source (i.e., a device) or a source to improve the transfer of heat from the heat generating device or source. The gap fillers or gap pads are well suited for fitting into complex and/or volume constrained devices, sources, components, or packages.

In certain embodiments, the gap fillers or gap pads may be used at temperatures which are above ambient temperature, at ambient temperature, below ambient temperature, below freezing, or at cryogenic temperatures.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

We claim:

1. A gap filler or gap pad comprising:
at least one compressible and/or compliant core component; and
at least one layer of a heat transporting and/or electrically conducting material wrapping the at least one compressible and/or compliant core component.

2. The gap filler or gap pad of claim 1, wherein the compressible and/or compliant core component comprises or is formed from an elastomer, a spring, a sponge, a foam, or a combination thereof.

3. The gap filler or gap pad of claim 2, wherein the elastomer is selected from the group consisting of a silicone rubber, natural rubbers, nitrile rubber, fluoropolymer elastomers, polyurethanes, ethylene propylene diene terpolymer rubber, styrene-butadiene rubber, neoprene, polyamide elastomers, and combinations thereof.

4. The gap filler or gap pad of claim 1, wherein the at least one layer of heat transporting and/or electrically conducting material is a flexible foil or sheet; or a flexible laminate material.

5. The gap filler or gap pad of claim 1, wherein the at least one layer of heat transporting and/or electrically conducting material is a flexible foil or sheet of a metal or a metal alloy; or a flexible graphite or synthetic graphite sheet; or a flexible laminate material comprising a carbon-based material optionally further comprising a foil or a foil comprising an array of carbon nanotubes.

6. The gap filler or gap pad of claim 5, wherein the metal or metal alloy is copper, aluminum, or alloy thereof.

7. The gap filler or gap pad of claim 5, wherein the carbon-based material comprises a graphitic carbon selected from graphite, single or multilayer graphene, reduced graphene oxide, carbon nanotubes, or combinations thereof.

8. The gap filler or gap pad of claim 1, wherein the at least one layer of heat transporting and/or electrically conducting material has a thermal conductivity in the range of between about 1-2500 W/m·K, 1-2000 W/m·K, 1-1500 W/m·K, 1-1000 W/m·K, 1-500 W/m·K, 5-500 W/m·K, 5-400 W/m·K, 5-300 W/m·K, 5-200 W/m·K, 5-150 W/m·K, 5-100 W/m·K, preferably 100-1900 W/m·K.

9. The gap filler or gap pad of claim 1, wherein the at least one layer of a heat transporting and/or electrically conducting material has an electrical resistance of less than about 1000, 900, 800, 700, 600, 500, 400, 300, 200, 100, 75, 50, 25, 20, 15, 10, 9, 8, 7, 6, 5, 4, 3, 2, 1, 0.9, 0.8, 0.7, 0.6, 0.5, 0.4, 0.3, 0.2, or 0.1 milliohms.

10. The gap filler or gap pad of claim 1, wherein the at least one layer of heat transporting and/or electrically conducting material wraps at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, or 99.9%, of the surface of the at least one compressible and/or compliant core component.

11. The gap filler or gap pad of claim 1, wherein there are two, three, four, five, six, seven, eight, nine, or more layers of the at least one layer of a heat transporting and/or electrically conducting material.

12. The gap filler or gap pad of claim 11, wherein the two, three, four, five, six, seven, eight, nine, or more layers of the at least one layer of a heat transporting and/or electrically conducting material are concentrically wrapped around the at least one compressible and/or compliant core component.

13. The gap filler or gap pad of claim 1, wherein the at least one layer of a heat transporting and/or electrically conducting material has a thickness in a range of between about 0 μm to 250 μm, preferably between 17 μm to 100 μm.

14. The gap filler or gap pad of claim 1, wherein the at least one compressible and/or compliant core component demonstrates a deflection of at least 25% or less when exposed pressure of about 100 psi, 90 psi, 80 psi, 70 psi, 60 psi, 50 psi, 40 psi, 30 psi, 20 psi, 15 psi, 10 psi, or 5 psi.

15. The gap filler or gap pad of claim 1, wherein the at least one compressible and/or compliant core component demonstrates a deflection of at least 100 microns or greater when exposed to a pressure of about 100 psi, 90 psi, 80 psi, 70 psi, 60 psi, 50 psi, 40 psi, 30 psi, 20 psi, 15 psi, 10 psi, or 5 psi.

16. The gap filler or gap pad of claim 1, wherein the compressible and/or compliant core component is heat resistant up to a temperature 100° C., 125° C., 150° C., 175° C., or 250° C., while retaining compressibility, compliance, and elastic recovery.

17. The gap filler or gap pad of claim 1, wherein the compressible and/or compliant core component is cold resistant down to a temperature of −10° C., −40° C., −55° C., −75° C., −160° C., −190° C., while retaining compressibility, compliance, and elastic recovery.

18. The gap filler or gap pad of claim 1, wherein the compressible and/or compliant core component comprises or is formed from an elastomer which is free or substantially free of silicone.

19. The gap filler or gap pad of claim 1, wherein the compressible and/or compliant core component has a compression set of less than about 25%, 20%, 15%, 10%, or 5% at 150° C., or 70° C.

20. The gap filler or gap pad of claim 1, wherein the compressible and/or compliant core component is in bar, sheet, or roll form.

21. The gap filler or gap pad of claim 1, wherein the compressible and/or compliant core component is a spring selected from a compression spring, a disc spring, a coned-disc spring, or a leaf spring made of a metal, plastic, or rubber.

22. The gap filler or gap pad of claim 1, wherein the at least one layer of a heat transporting and/or electrically conducting material is adhesive or comprises an adhesive and is bonded to all or substantially all of the surface of the at least one compressible and/or compliant core component

23. The gap filler or gap pad of claim 1, wherein the gap filler or gap pad further comprises:
an interfacing material present on at least one surface of the heat transporting and/or electrically conducting material surrounding the at least one compressible and/or compliant core component.

24. The gap filler or gap pad of claim 23, wherein the interfacing material is formed of or comprises a carbon nanotube array optionally comprising a metal substrate; or a graphite.

25. The gap filler or gap pad of claim 23, wherein the interfacing material is a laminate, sheet, pad, or tape.

26. The gap filler or gap pad of claim 23, wherein the interfacing material is adhesive or comprises an adhesive.

27. The gap filler or gap pad of claim 1, wherein the at least one layer of a heat transporting and/or electrically conducting material acts as an electrical shield that prevents all or substantially all of the transmission of an incident electromagnetic wave.

28. The gap filler or gap pad of claim 1, which produces a return loss of greater than 20 dB, 30 dB, 40 dB, or 50 dB when subjected to scattering parameter testing when placed in contact with a waveguide flange.

29. The gap filler or gap pad of claim 1 which produces an insertion loss of less than 0.5 dB, 0.4 dB, 0.3 dB, or 0.1 dB when subjected to scattering parameter testing when placed in contact with a waveguide flange.

30. A device wherein the gap pad or gap filler of claim 1 is present between a heat generating source and a heat sink.

31. A device wherein the gap pad or gap filler of claim 1 is present on a pedestal used for temperature control and shows less than 15% compression set after 10, 100, 1000, 10000, 100,000 or 1 million insertion or device engagement cycles.

32. A method of forming the gap pad or gap filler of claim 1 comprising the steps of:
(a) providing at least one compressible and/or compliant core component; and at least one heat transporting and/or electrically conducting material; and
(b) wrapping the at least one heat transporting and/or electrically conducting material around the at least one compressible and/or compliant core component; and
wherein step (b) optionally includes applying an adhesive to the at least one heat transporting and/or electrically conducting material to maintain the position of the wrapped at least one heat transporting and/or electrically conducting material on the compressible core.

33. The method of claim 32, wherein the compressible and/or compliant core component comprises or is formed from an elastomer, a spring, a sponge, a foam, or a combination thereof.

34. The method of claim 33, wherein the elastomer is selected from the group consisting of a silicone rubber, natural rubbers, nitrile rubber, fluoropolymer elastomers, polyurethanes, ethylene propylene diene terpolymer rubber, styrene-butadiene rubber, neoprene, polyamide elastomers, and combinations thereof.

35. The method of claim 32, wherein the at least one layer of heat transporting and/or electrically conducting material is a flexible foil or sheet; or a flexible laminate material.

36. The method of claim 32, wherein the at least one layer of heat transporting and/or electrically conducting material is a flexible foil or sheet of a metal or a metal alloy; or a flexible graphite or synthetic graphite sheet; or a flexible laminate material comprising a carbon-based material optionally further comprising a foil or a foil comprising an array of carbon nanotubes.

37. The method of claim 36, wherein the metal is copper or aluminum.

38. The method of claim 36, wherein the carbon-based material comprises a graphitic carbon selected from graphite, single or multilayer graphene, reduced graphene oxide, carbon nanotubes, and combinations thereof.

39. The method of claim 32, wherein the at least one layer of heat transporting and/or electrically conducting material wraps at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, or 99.9%, of the surface of the at least one compressible and/or compliant core component.

40. The method of claim 32, wherein there are two, three, four, five, six, seven, eight, nine, or more layers of the at least one layer of heat transporting and/or electrically conducting material.

41. The method of claim 40, wherein the two, three, four, five, six, seven, eight, nine, or more layers of the at least one layer of a heat transporting and/or electrically conducting material which are concentrically wrapped around the at least one compressible and/or compliant core component.

42. The method of claim 32, wherein the at least one layer of a heat transporting and/or electrically conducting material has a thickness in a range of between about 0 μm to 250 μm, preferably between 17 μm to 100 μm.

43. The method of claim 32, wherein the compressible and/or compliant core component is in bar, sheet, or roll form.

44. The method of claim 32, wherein the compressible and/or compliant core component is a spring selected from a compression spring, a disc spring, a coned-disc spring, or a leaf spring made of a metal, plastic, or rubber.

45. The method of claim 32, wherein the at least one layer of a heat transporting and/or electrically conducting material is adhesive or comprises an adhesive and is bonded to all or substantially all of the surface of the at least one compressible and/or compliant core component

46. The method of claim 32, further comprising:
(c) providing an interfacing material; and
(d) contacting the interfacing material to at least one surface of the heat transporting and/or electrically conducting material wrapped around the at least one compressible and/or compliant core component.

47. The method of claim 46, wherein the interfacing material is formed of or comprises a carbon nanotube array optionally comprising a metal substrate; or a graphite.

48. The method of claim 46, wherein the interfacing material is a laminate, sheet, pad, or tape.

49. The method of claim 46, wherein the interfacing material is wrapped around all or substantially all of the heat transporting and/or electrically conducting material's surface.

50. The method of claim 46, wherein the interfacing material is adhesive or comprises an adhesive.
